(19) United States
(12) Patent Application Publication
(10) Pub. No.: US 2024/0421096 A1
(43) Pub. Date: Dec. 19, 2024

(54) MANUFACTURING METHOD OF ELECTRONIC PACKAGE AND ELECTRONIC PACKAGE

(71) Applicant: VIA Technologies, Inc., New Taipei City (TW)

(72) Inventors: Wen-Yuan Chang, New Taipei City (TW); Wei-Cheng Chen, New Taipei City (TW); Chen-Yueh Kung, New Taipei City (TW)

(73) Assignee: VIA Technologies, Inc., New Taipei City (TW)

(21) Appl. No.: 18/476,281

(22) Filed: Sep. 27, 2023

(30) Foreign Application Priority Data
Jun. 16, 2023 (TW) 112122520

(51) Int. Cl. H01L 23/538; H01L 23/00; H01L 25/065

(52) U.S. Cl. CPC H01L 23/5386; H01L 24/08; H01L 24/09; H01L 24/16; H01L 24/19; H01L 24/24; H01L 24/73; H01L 25/0655; H01L 2224/08245; H01L 2224/0903; H01L 2224/16225; H01L 2224/19; H01L 2224/24225; H01L 2224/73209; H01L 2924/15331; H01L 2924/18161

(57) ABSTRACT

A manufacturing method of an electronic package includes the following steps. Multiple chips are temporarily fixed to a temporary carrier. At least one bridge element is installed on the adjacent chips. A base dielectric layer covering a temporary bonding layer, the chips, and the bridge element is formed. A material of the base dielectric layer includes a silicate composite material. Multiple base conductive vias and a redistribution structure are respectively formed on the chips and the base dielectric layer. Multiple conductive bumps are formed on the redistribution structure. In addition, an electronic package is also provided, which may be produced by the manufacturing method.

### CROSS-REFERENCE TO RELATED APPLICATION

This application claims the priority benefit of Taiwan application serial no. 112122520, filed on Jun. 16, 2023. The entirety of the above-mentioned patent application is hereby incorporated by reference herein and made a part of this specification.

### BACKGROUND

### Technical Field

The disclosure relates to an electronic component, and in particular relates to a manufacturing method of an electronic package and an electronic package.

### Description of Related Art

There are many types of electronic packaging technologies currently used for multi-chips, one of which is to form a redistribution structure on a bridge element, and then bond multiple chips to the redistribution structure in a flip-chip manner. Therefore, the bridge element overlapping with the adjacent chips can shorten the signal transmission path between the adjacent chips. In order to protect the chips and the bridge element, a conventional method is to adopt a molding compound to cover the bridge element and the chips. However, even if the chips are correctly positioned, the injection of the molding compound may still cause alignment shift of the chips, and the thermal curing process of the molding compound may accumulate stress on the contact surface between the chips and the material due to the large difference in thermal expansion coefficient.

### SUMMARY

The disclosure provides a manufacturing method of an electronic package, which is used to manufacture the electronic package.

The disclosure provides an electronic package, which is used to provide preferable packaging quality.

A manufacturing method of an electronic package according to an embodiment of the disclosure includes the following steps. Multiple chips are fixed to a temporary carrier via a temporary bonding layer. At least one bridge element is installed on active surfaces of the adjacent chips, so that the bridge element respectively partially overlaps with the adjacent chips. Multiple bridging pads of the bridge element are respectively directly bonded to multiple first chip pads of the active surfaces of the adjacent chips. A base dielectric layer is formed to cover the temporary bonding layer, the chips, and the bridge element, and the base dielectric layer fills a gap between adjacent two of the chips. A material of the base dielectric layer is a silicate composite material or a material available for chemical-mechanical polishing. The bridge element and the base dielectric layer are thinned and planarized. Multiple base conductive vias are formed. The base conductive vias respectively pass through the base dielectric layer and are respectively connected to multiple second chip pads of the active surfaces of the chips. A redistribution structure is formed on the base dielectric layer and the base conductive vias. Multiple conductive bumps are formed on the redistribution structure. The temporary bonding layer and the temporary carrier are removed to expose a back surface of each of the chips.

An electronic package according to an embodiment of the disclosure includes a sub-package. The sub-package includes multiple chips, at least one bridge element, a base dielectric layer, multiple base conductive vias, a redistribution structure, and multiple conductive bumps. The chips are arranged on a plane. The at least one bridge element respectively partially overlaps with the adjacent chips. Multiple bridging pads of the bridge element are respectively directly bonded to multiple first chip pads of active surfaces of the adjacent chips. The base dielectric layer covers the chips and the bridge element, and exposes back surfaces of the chips, and the base dielectric layer fills a gap between adjacent two of the chips. A material of the base dielectric layer includes a silicate composite material or a material suitable for chemical-mechanical polishing. The base conductive vias pass through the base dielectric layer and are respectively connected to multiple second chip pads of the active surfaces of the chips. The redistribution structure is disposed on the base dielectric layer and the base conductive vias. The conductive bumps are disposed on the redistribution structure.

Based on the above, the material of the base dielectric layer can reduce the interface stress between the material and each chip, so that the control of the material and processing is easier to obtain a finished product with high reliability. Moreover, the direct copper bond of the bridge element to the chips also helps to drastically improve transmission performance and power cost performance ratio. In other words, the bridging pads of the bridge element are respectively directly bonded to the first chip pads of the active surfaces of the adjacent chips, which helps to reduce circuit power, increase bridging density, and achieve high-performance computing applications.

### BRIEF DESCRIPTION OF THE DRAWINGS

FIG. 1A to FIG. 1H illustrate a manufacturing method of an electronic package according to an embodiment of the disclosure.

FIG. 2A to FIG. 21 illustrate a manufacturing method of an electronic package according to another embodiment of the disclosure.

FIG. 3 illustrates an electronic package according to another embodiment of the disclosure.

### DESCRIPTION OF THE EMBODIMENTS

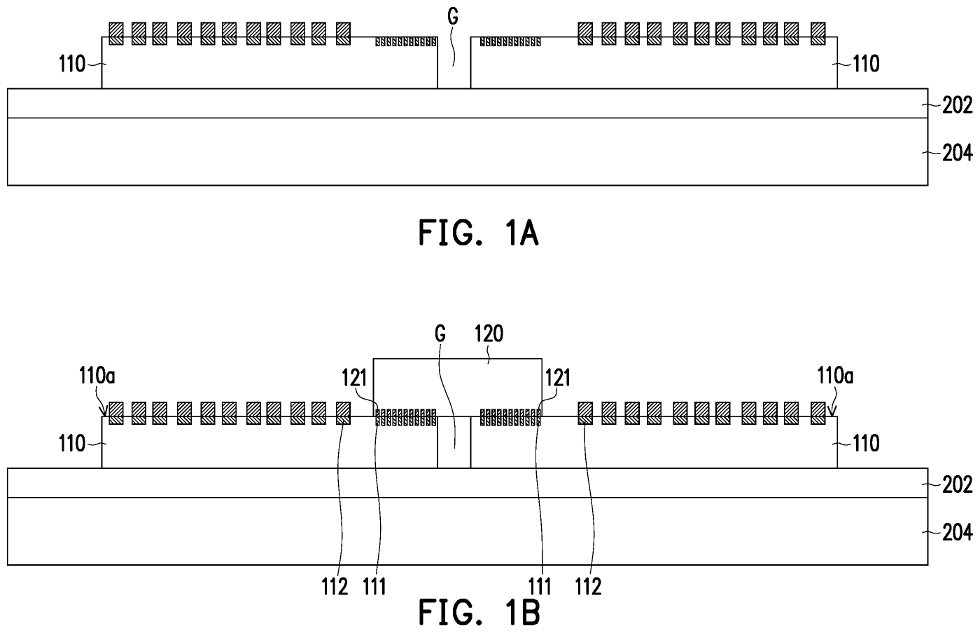

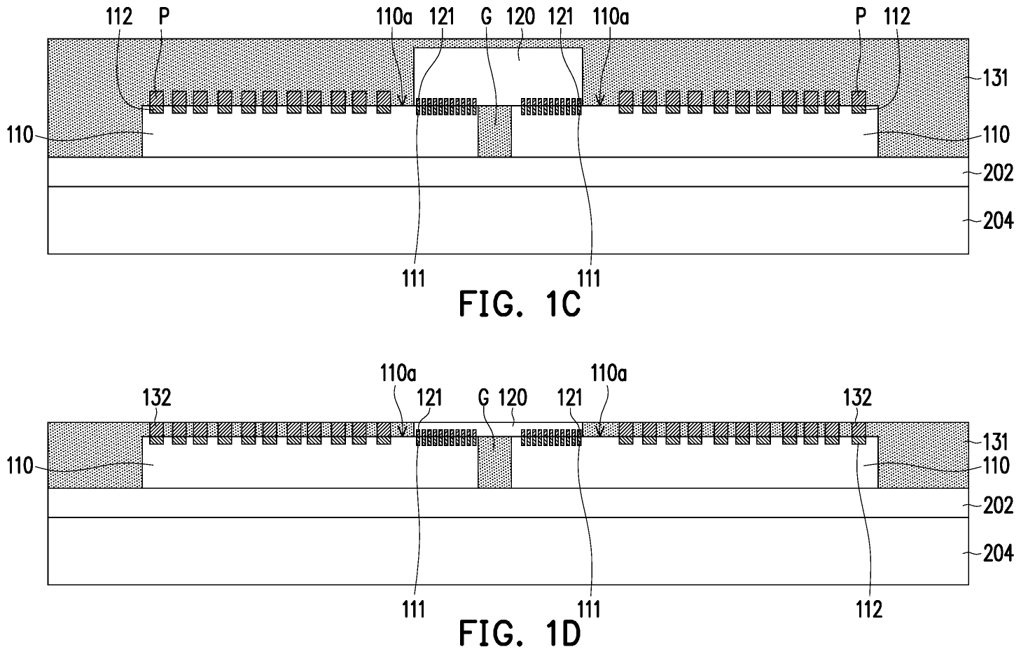

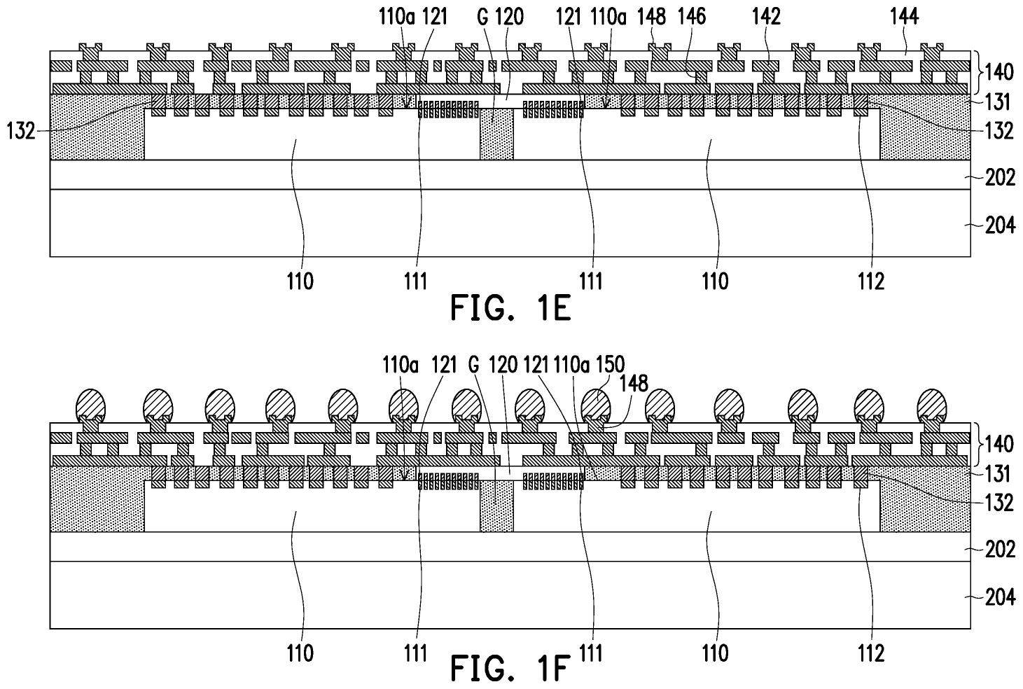

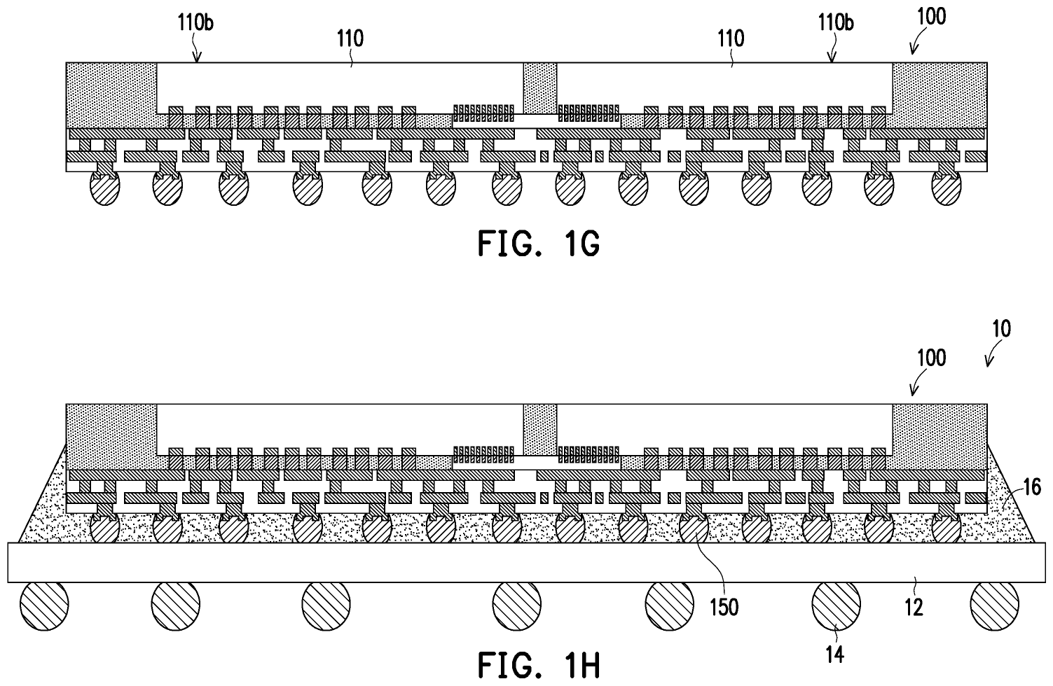

A manufacturing method of an electronic package according to an embodiment of the disclosure will be described below with reference to FIG. 1A to FIG. 1I.

Please refer to FIG. 1A. Multiple chips 110 are fixed to a temporary carrier 204 via a temporary bonding layer 202. In the embodiment, the temporary bonding layer 202 may be a release film.

In the embodiment, one of the chips 110 may be a central processing unit chip, a logic chip, a graphics processing chip, an input/output chip, a memory chip, a base band chip, a radio frequency (RF) chip, or an integrated circuit chip with a specific function. In other words, the chips 110 may include a combination of the chips of different functional types, so that the electronic package may be used in a chiplet packaging technology, which is similar to system in package (SiP). Since the chips 110 may have different functions, the sizes of the chips 110 may be different. In some embodiments, the chips may be a combination of a central processing unit chip and a logic chip, a combination of a central processing unit chip and an input/output chip, a combination of a graphics processing chip and a memory chip, or a combination of a radio frequency chip and a base band chip, and may also be a combination of two chips with the same function.

Please refer to FIG. 1B. At least one bridge element 120 is installed on active surfaces 110a of the adjacent chips 110, so that the bridge element 120 partially overlaps with the adjacent chips 110. Multiple bridging pads 121 of the bridge element 120 are respectively directly bonded to multiple first chip pads 111 of the active surfaces 110a of the adjacent chips 110. In other words, an active surface of the bridge element 120 and a part of the active surface of each of the chips 110 are in contact with each other. Therefore, the adjacent chips 110 may be electrically connected to each other via the bridge element 120 to shorten a signal transmission path between the chips 110. In addition, in the embodiment, although one bridge element being connected to two chips is used as an example, the disclosure is not limited thereto. In some embodiments, there may be more than two chips, and the bridge element is not limited to one, which may be determined depending on requirements.

In an embodiment, the material of the bridge element 120 may include an inorganic material such as silicon, glass, and ceramics or an organic material. The bridge element 120 may be an active element or a passive element. Furthermore, in the embodiment, the connection between the bridge element 120 and the chip 110 is a direct connection (pad to pad) between the bridging pad 121 and the first chip pad 111. Compared with the prior art in which each chip is connected to a bridge element through a redistribution structure (a redistribution layer, RDL), the embodiment can further shorten the transmission distance of electrical signals between the chips, and there is less issue of alignment shift. Furthermore, in an embodiment, the size of the first chip pad 111 is not greater than the size of a second chip pad 112. The pitch of two adjacent first chip pads 111 is not greater than the pitch of two adjacent second chip pads 112, and the pitch of two adjacent first chip pads 111 is, for example, less than 10 μm. In addition, the distribution density of the first chip pads 111 may be greater than the distribution density of the second chip pads 112.

Please refer to FIG. 1C. A base dielectric layer 131 covering the temporary bonding layer 202, the chips 110, and the bridge element 120 is formed, and the base dielectric layer 131 fills a gap G between two adjacent chips 110. The material of the base dielectric layer 131 includes a silicate composite material or a material suitable for chemical-mechanical polishing (CMP). The silicate composite material is preferably a silicate nanocomposite material. The material suitable for chemical-mechanical polishing is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the base dielectric layer 131. In addition, the above materials have a relatively low coefficient of thermal expansion (CTE). The coefficient of thermal expansion is, for example, less than 10 ppm/° C., and more preferably may be controlled to be less than 5 ppm/° C. Therefore, the coefficient of thermal expansion of the base dielectric layer 131 is similar to the coefficient of thermal expansion of silicon. In other words, the coefficient of thermal expansion of the base dielectric layer 131 is similar to the coefficient of thermal expansion of the chip 110, so that warpage of the chip caused by a large difference between the thermal expansion coefficients of the chip 110 and the base dielectric layer 131 in the past can be prevented. In the embodiment, the base dielectric layer 131 may be formed by spray coating, spin coating, or deposition. It is worth mentioning that in known packaging technologies, the molding compounds are often used to cover the chips, but the coefficient of thermal expansion of the molding compounds is much greater than the coefficient of thermal expansion of the chips. Moreover, the particles of the molding compounds are larger, so the particles may not easily fill gaps, and the molding compounds are also prone to stress. However, the disclosure uses a nanometer-scale material with a coefficient of thermal expansion close to the coefficient of thermal expansion of silicon. The material has smaller particles and better filling capability, so the material may effectively fill the gap. In the embodiment, the base dielectric layer 131 may fill the gap G between two adjacent chips 110. In addition, in an embodiment, the base dielectric layer 131 does not fill a gap between two adjacent bridging pads 121, nor does the base dielectric layer 131 fill a gap between two adjacent first chip pads 111.

In addition, each of the chips 110 has multiple conductive pillars P, and the conductive pillars P are respectively located on multiple second chip pads 112 of the active surfaces 110a of the chips 110. Therefore, in the step of forming the base dielectric layer 131, the base dielectric layer 131 covers the conductive pillars P.

Please refer to FIG. 1D. The bridge element 120 and the base dielectric layer 131 are thinned and planarized. At this time, the base dielectric layer 131 exposes the conductive pillars P. In the embodiment, chemical-mechanical polishing may be adopted for thinning and planarization. Through this step, in some cases, the issue of different thicknesses of the chips 110 on the temporary bonding layer 202 can be solved. In an embodiment, the thickness of the thinned bridge element 120 is less than the thickness of the chips 110. In addition, through the step of thinning and planarizing the bridge element 120 and the base dielectric layer 131, the overall thickness of the electronic package can become thinner, so that the thinned electronic package may be applied in thinner and lighter products. In the step of thinning and planarizing the bridge element 120 and the base dielectric layer 131, the conductive pillars P shown in FIG. 1C are shortened and exposed from the base dielectric layer 131 to form the base conductive vias 132. In addition, the base conductive vias 132 may form a contact array with a contoured plane, and the base conductive vias 132 may also be subjected to surface treatment and activation.

Please refer to FIG. 1E again. A redistribution structure 140 is formed on the base dielectric layer 131 and the base conductive vias 132. In the embodiment, the chip 110 is electrically connected to the base conductive vias 132 and the redistribution structure 140 using the second chip pads 112, and the chip 110 is electrically connected to the bridge element 120 using the first chip pads 111 and the bridging pads 121.

In the embodiment, the redistribution structure 140 may be formed by a build-up process. The redistribution structure 140 may include multiple redistribution patterned conductive layers 142, multiple redistribution dielectric layers 144, and multiple redistribution conductive vias 146. The redistribution patterned conductive layers 142 are alternately stacked with the redistribution dielectric layers 144. The redistribution conductive vias 146 are respectively connected to the redistribution patterned conductive layers 142. In addition, multiple under bump metallurgy (UBM) layers 148 are further formed on multiple parts of the redistribution patterned conductive layer 142 farthest from the chips 110.

Please refer to FIG. 1F. Multiple conductive bumps 150 are formed on the redistribution structure 140. In the embodiment, the conductive bumps 150 may be respectively formed on the under bump metallurgy layers 148 of the redistribution structure 140.

Please refer to FIG. 1G. The temporary bonding layer 202 and the temporary carrier 204 are removed to expose a back surface 110b of each of the chips 110. So far, a sub-package 100 is completed.

Please refer to 1H. The conductive bumps 150 are connected to a circuit carrier 12, and multiple conductive balls 14 are connected to the circuit carrier 12. In the embodiment, after the conductive bumps 150 are connected to the circuit carrier 12, an underfill 16 may be filled between the sub-package 100 and the circuit carrier 12 to cover the conductive bumps 150. So far, an electronic package 10 is completed.

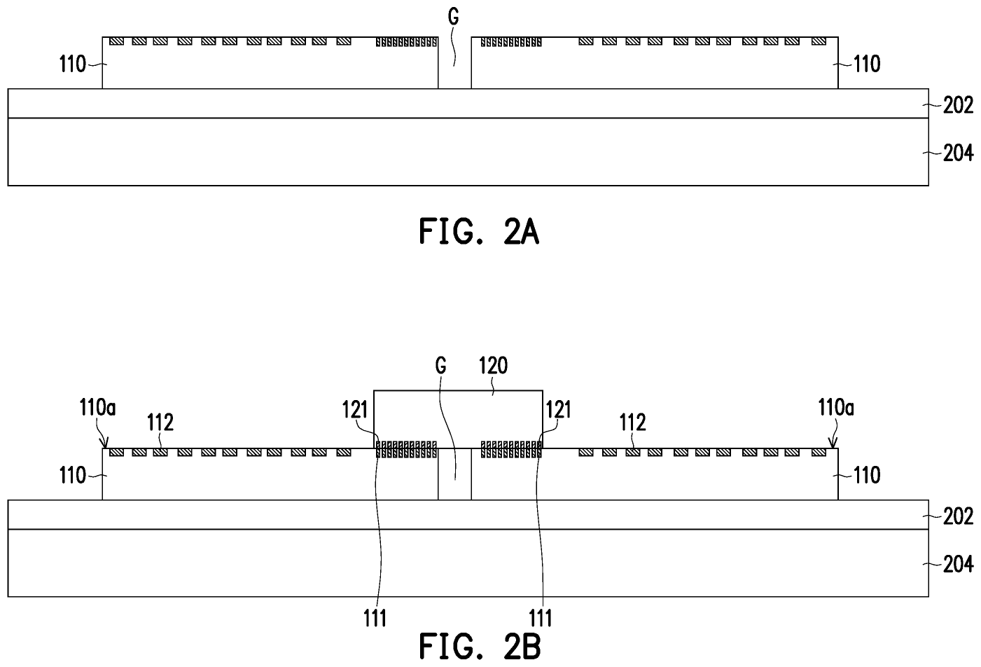

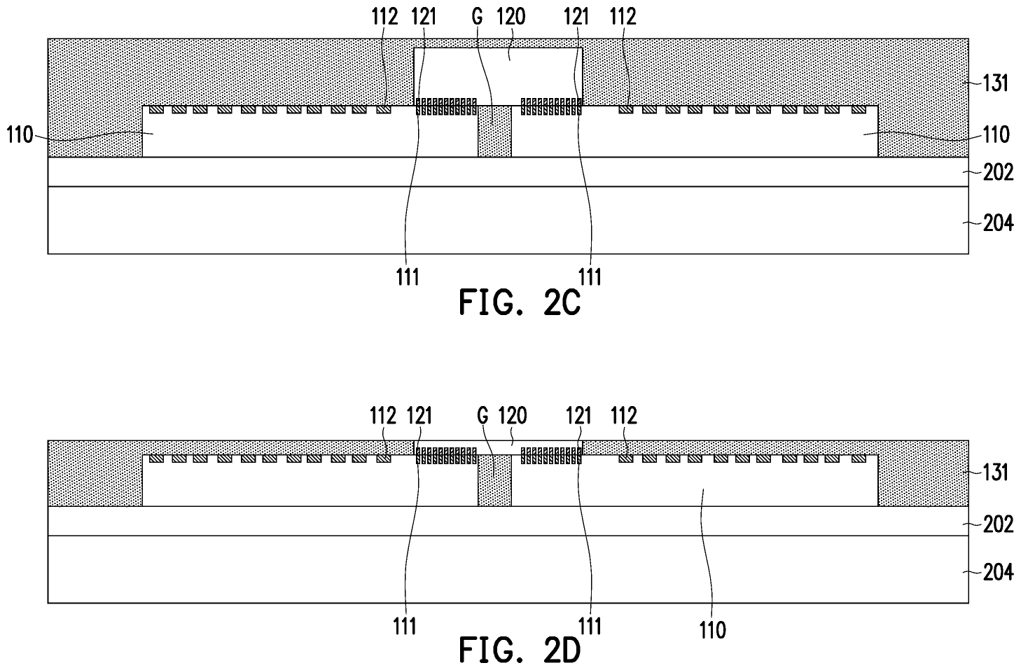

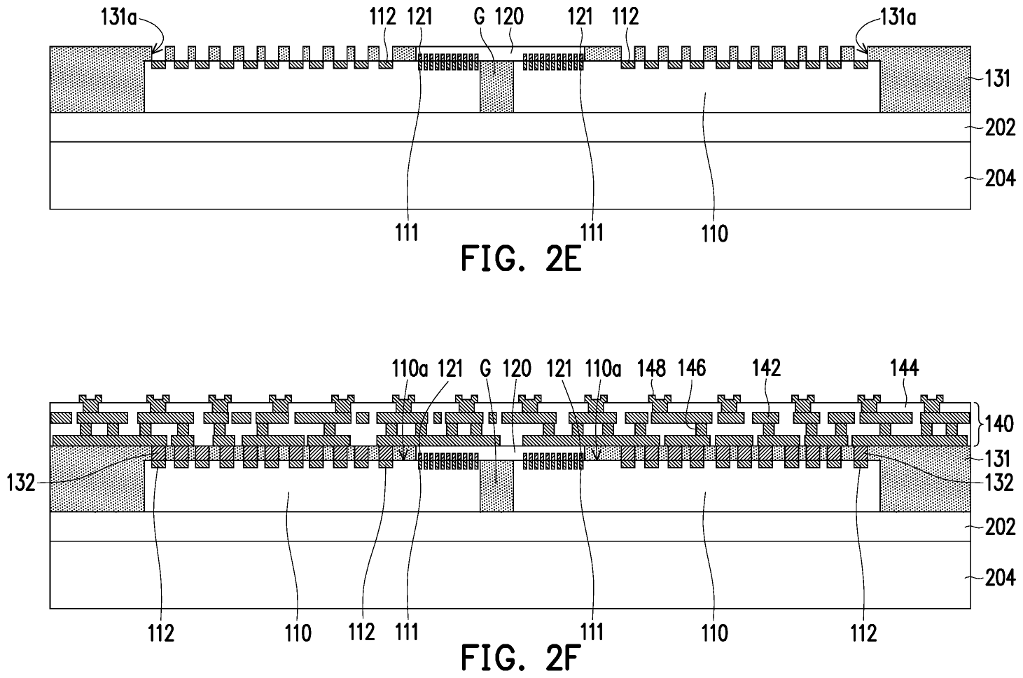

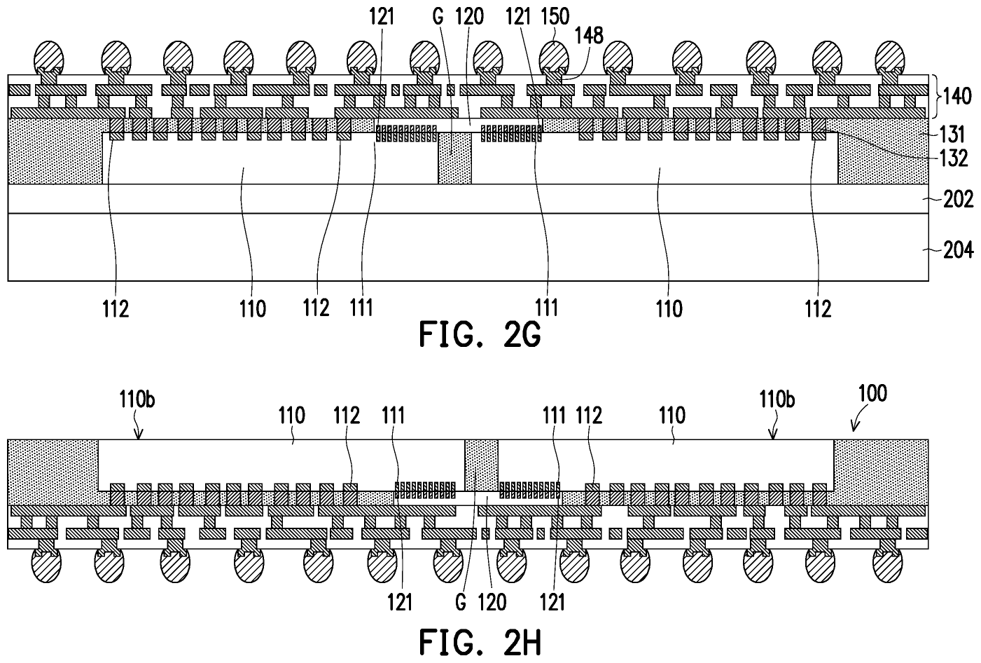

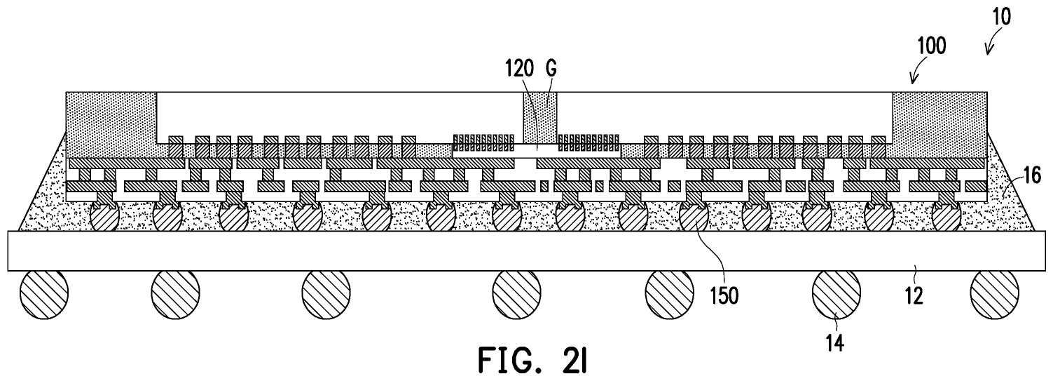

A manufacturing method of an electronic package according to another embodiment of the disclosure will be described below with reference to FIG. 2A to FIG. 2I.

Please refer to FIG. 2A. The chips 110 are fixed to the temporary carrier 204 via the temporary bonding layer 202. In the embodiment, the temporary bonding layer 202 may be a release film.

In the embodiment, one of the chips 110 may be a central processing unit chip, a logic chip, a graphics processing chip, an input/output chip, a memory chip, a base band chip, a radio frequency (RF) chip, or an integrated circuit chip with a specific function. In other words, the chips 110 may include a combination of the chips of different functional types, so that the electronic package may be used in a chiplet packaging technology, which is similar to system in package (SiP). Since the chips 110 may have different functions, the sizes of the chips 110 may be different. In some embodiments, the chips may be a combination of a central processing unit chip and a logic chip, a combination of a central processing unit chip and an input/output chip, a combination of a graphics processing chip and a memory chip, or a combination of a radio frequency chip and a base band chip, and may also be a combination of two chips with the same function.

Please refer to FIG. 2B. The at least one bridge element 120 is installed on the active surfaces 110a of the adjacent chips 110, so that the bridge element 120 respectively partially overlaps with the adjacent chips 110. The bridging pads 121 of the bridge element 120 are respectively directly bonded to the first chip pads 111 of the active surfaces 110a of the adjacent chips 110. In other words, the active surface of the bridge element 120 and a part of the active surface 110a of each of the chips 110 are in contact with each other. Therefore, the adjacent chips 110 may be electrically connected to each other through the bridge element 120 to shorten the signal transmission path between the chips 110. In addition, in the embodiment, although one bridge element being connected to two chips is used as an example, the disclosure is not limited thereto. In some embodiments, there may be more than two chips, and the bridge element is not limited to one, which may be determined depending on requirements.

In an embodiment, the material of the bridge element 120 may include an inorganic material such as silicon, glass, and ceramics or an organic material. The bridge element 120 may be an active element or a passive element. Furthermore, in the embodiment, the connection between the bridge element 120 and the chip 110 is a direct connection (pad to pad) between the bridging pad 121 and the first chip pad 111. Compared with the prior art in which each chip is connected to the bridge element through a redistribution structure (a redistribution layer, RDL), the embodiment can further shorten the transmission distance of electrical signals between the chips, and there is less issue of alignment shift. Furthermore, in an embodiment, the size of the first chip pad 111 is not greater than the size of the second chip pad 112. The pitch of two adjacent first chip pads 111 is not greater than the pitch of two adjacent second chip pads 112, and the pitch of two adjacent first chip pads 111 is, for example, less than 10 μm. In addition, the distribution density of the first chip pads 111 may be greater than the distribution density of the second chip pads 112.

Please refer to FIG. 2C. The base dielectric layer 131 covering the temporary bonding layer 202, the chips 110, and the bridge element 120 is formed, and the base dielectric layer 131 fills the gap G between two adjacent chips 110. The material of the base dielectric layer 131 includes a silicate composite material or a material suitable for chemical-mechanical polishing. The silicate composite material is preferably a silicate nanocomposite material. The material suitable for chemical-mechanical polishing is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the base dielectric layer 131. In addition, the above materials have a relatively low coefficient of thermal expansion. The coefficient of thermal expansion is, for example, less than 10 ppm/° C., and more preferably may be controlled to be less than 5 ppm/° C. Therefore, the coefficient of thermal expansion of the base dielectric layer 131 is similar to the coefficient of thermal expansion of silicon. In other words, the coefficient of thermal expansion of the base dielectric layer 131 is similar to the coefficient of thermal expansion of the chip 110, so that warpage of the chip caused by a large difference between the thermal expansion coefficients of the chip 110 and the base dielectric layer 131 in the past can be prevented. In the embodiment, the base dielectric layer 131 may be formed by spray coating, spin coating, or deposition. It is worth mentioning that in known packaging technologies, the molding compounds are often used to cover the chips, but the coefficient of thermal expansion of the molding compounds is much greater than the coefficient of thermal expansion of the chips. Moreover, the particles of the molding compounds are larger, so the particles may not easily fill gaps, and the molding compounds are also prone to stress. However, the disclosure uses a nanometer-scale material with a coefficient of thermal expansion close to the coefficient of thermal expansion of silicon. The material has smaller particles and better filling capability, so the material may effectively fill the gap. In the embodiment, the base dielectric layer 131 may fill the gap G between two adjacent chips 110. In addition, in an embodiment, the base dielectric layer 131 does not fill the gap between two adjacent bridging pads 121, nor does the base dielectric layer 131 fill the gap between two adjacent first chip pads 111.

Please refer to FIG. 2D. The bridge element 120 and the base dielectric layer 131 are thinned and planarized. In the embodiment, chemical-mechanical polishing may be adopted for thinning and planarization. Through this step, in some cases, the issue of different thicknesses of the chips 110 on the temporary bonding layer 202 can be solved. Therefore, after the step of thinning and planarization, a back surface of the bridge element 120 and the base dielectric layer 131 may form a coplanar surface. In an embodiment, the thickness of the thinned bridge element 120 is less than the thickness of the chips 110. In addition, through the step of thinning and planarizing the bridge element 120 and the base dielectric layer 131, the overall thickness of the electronic package can become thinner, so that the thinned electronic package may be applied in thinner and lighter products.

Please refer to FIG. 2E. Multiple parts of the base dielectric layer 131 are removed to form multiple via holes 131a. The parts of the base dielectric layer 131 may be removed by photolithography and etching.

Please refer to FIG. 2F. A conductive material may be filled in the via holes 131a shown in FIG. 2E to form the base conductive vias 132. At this time, the base dielectric layer 131 exposes the base conductive vias 132. The base conductive vias 132 respectively pass through the base dielectric layer 131 and are respectively connected to the second chip pads 112 of the active surfaces 110a of the chips 110. The conductive material may be filled by electroplating.

Please refer to FIG. 2F again. The redistribution structure 140 is formed on the base dielectric layer 131 and the base conductive vias 132. In the embodiment, the first chip 110 is electrically connected to the base conductive vias 132 and the redistribution structure 140 using the second chip pads 112, and the first chip 110 is electrically connected to the bridge element 120 using the first chip pads 111 and the bridging pads 121.

In the embodiment, the redistribution structure 140 may be formed by a build-up process. The redistribution structure 140 may include the redistribution patterned conductive layers 142, the redistribution dielectric layers 144, and the redistribution conductive vias 146. The redistribution patterned conductive layers 142 are alternately stacked with the redistribution dielectric layers 144. The redistribution conductive vias 146 are respectively connected to the redistribution patterned conductive layers 142. In addition, the under bump metallurgy layers 148 are further formed on the parts of the redistribution patterned conductive layer 142 farthest from the chips 110. During the process of forming the redistribution structure 140, the conductive material may also be filled in the via holes 131a of the base dielectric layer 131 to form the base conductive vias 132.

Please refer to FIG. 2G. The conductive bumps 150 are formed on the redistribution structure 140. In the embodiment, the conductive bumps 150 may be respectively formed on the under bump metallurgy layers 148 of the redistribution structure 140.

Please refer to FIG. 2H. The temporary bonding layer 202 and the temporary carrier 204 are removed to expose the back surface 110b of each of the chips 110. So far, the sub-package 100 is completed.

Please refer to FIG. 21. The conductive bumps 150 are connected to the circuit carrier 12, and the conductive balls 14 are connected to the circuit carrier 12. In the embodiment, after the conductive bumps 150 are connected to the circuit carrier 12, the underfill 16 may be filled between the sub-package 100 and the circuit carrier 12 to cover the conductive bumps 150. The electronic package 10 is completed.

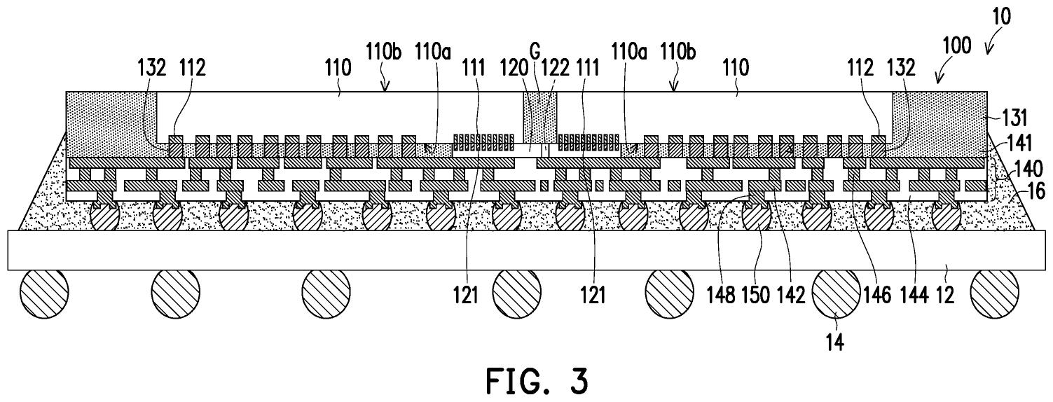

The electronic package 10 according to an embodiment of the disclosure will be described below with reference to FIG. 3 and may be produced by the manufacturing method of the above embodiment or other manufacturing methods.

Please refer to FIG. 3. In the embodiment, the electronic package 10 includes one or more sub-packages 100. FIG. 2 only takes one sub-package 100 as an example. The sub-package 100 includes the chips 110, the at least one bridge element 120, the base dielectric layer 131, the base conductive vias 132, the redistribution structure 140, and the conductive bumps 150. The chips 110 are arranged on a plane. The bridge element 120 respectively partially overlaps with the adjacent chips 110. The bridging pads 121 of the bridge element 120 are respectively directly bonded to the first chip pads 111 of the active surfaces 110a of the adjacent chips 110.

The base dielectric layer 131 covers the chips 110 and the bridge element 120, and exposes the back surfaces 110b of the chips 110, and the base dielectric layer 131 fills the gap G between two adjacent chips 110. The material of the base dielectric layer 131 includes a silicate composite material or a material suitable for chemical-mechanical polishing. The silicate composite material is preferably a silicate nanocomposite material. The material suitable for chemical-mechanical polishing is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the base dielectric layer 131.

The base conductive vias 132 pass through the base dielectric layer 131 and are respectively connected to the second chip pads 112 of the active surfaces 110a of the chips 110. The redistribution structure 140 is disposed on the base dielectric layer 131 and the base conductive vias 132. The conductive bumps 150 are disposed on the redistribution structure 140.

In the embodiment, the base dielectric layer 131 may fill the gap G between two adjacent chips 110. The base dielectric layer 131 has a material with a relatively low coefficient of thermal expansion. The coefficient of thermal expansion is, for example, less than 10 ppm/° C., and more preferably may be controlled to be less than 5 ppm/° C. Therefore, the coefficient of thermal expansion of the base dielectric layer 121 is similar to the coefficient of thermal expansion of silicon. In other words, the coefficient of thermal expansion of the base dielectric layer 131 is similar to the coefficient of thermal expansion of the chip 110, so that warpage of the chip caused by a large difference between the thermal expansion coefficients of the chip 110 and the base dielectric layer 131 in the past can be prevented.

In the embodiment, the distribution density of the first chip pads 111 may be greater than the distribution density of the second chip pads 112.

In the embodiment, one of the chips 110 may be a central processing unit chip, a logic chip, a graphics processing chip, an input/output chip, a memory chip, a base band chip, a radio frequency (RF) chip, or an integrated circuit chip with a specific function. In other words, the chips 110 may include a combination of the chips of different functional types, so that the electronic package 10 may be used in a chiplet packaging technology, which is similar to system in package (SiP). Since the chips 110 may have different functions, the sizes of the chips 110 may be different. In some embodiments, the chips may be a combination of a central processing unit chip and a logic chip, a combination of a central processing unit chip and an input/output chip, a combination of a graphics processing chip and a memory chip, or a combination of a radio frequency chip and a base band chip. In some embodiments, the chips may also be a combination of two chips with the same function.

In the embodiment, the bridge element 120 may be an active element or a passive element. The material of the bridge element 120 may include an inorganic material (for example, silicon, glass, and ceramics) or an organic material. The bridge element 120 may have multiple bridge conductive vias 122, and the chips 110 are electrically connected to the redistribution structure 140 via the bridge conductive vias 122. In addition, the thickness of the bridge element 120 is less than the thickness of the chips 110.

In the embodiment, the electronic package 10 may include the circuit carrier 12. The sub-package 100 is installed on the circuit carrier 12. In addition, the electronic package 10 may further include the conductive balls 14. The conductive balls 14 are connected to the circuit carrier 12. In addition, the electronic package 10 may further include the underfill 16. The underfill 16 is filled between the redistribution structure 140 and the circuit carrier 12, and covers the conductive bumps 150.

In summary, in the above embodiments, the material of the base dielectric layer can reduce the interface stress between the material and each chip, especially at the junction of the horizontal and vertical planes of the chip, so that the control of the material and processing is easier to obtain a finished product with high reliability. Moreover, the direct copper bond of the bridge element to the chips also helps to drastically improve transmission performance and power cost performance ratio. In other words, the bridging pads of the bridge element are respectively directly bonded to the first chip pads of the active surfaces of the adjacent chips, which helps to reduce circuit power, increase bridging density, and achieve high-performance computing applications. Under the selected material of the base dielectric layer, when the base dielectric layer is formed by spray coating, spin coating, or deposition, the gap between adjacent chips may be easily filled at low temperature, and the formation of the base dielectric layer is less likely to cause deflection of the chips to maintain alignment precision.

What is claimed is:

1. A manufacturing method of an electronic package, comprising:
fixing a plurality of chips to a temporary carrier via a temporary bonding layer;
installing at least one bridge element on active surfaces of the adjacent chips, so that the bridge element respectively partially overlaps with the adjacent chips, wherein a plurality of bridging pads of the bridge element are respectively directly bonded to a plurality of first chip pads of the active surfaces of the adjacent chips;
forming a base dielectric layer covering the temporary bonding layer, the chips, and the bridge element, wherein the base dielectric layer fills a gap between adjacent two of the chips, and a material of the base dielectric layer comprises a silicate composite material or a material suitable for chemical-mechanical polishing;
thinning and planarizing the bridge element and the base dielectric layer;
forming a plurality of base conductive vias, wherein the base conductive vias respectively pass through the base dielectric layer and are respectively connected to a plurality of second chip pads of the active surfaces of the chips;
forming a redistribution structure on the base dielectric layer and the base conductive vias;
form a plurality of conductive bumps on the redistribution structure; and
removing the temporary bonding layer and the temporary carrier to expose a back surface of each of the chips.

2. The manufacturing method of the electronic package according to claim 1, wherein each of the chips has a plurality of conductive pillars, the conductive pillars are respectively located on the corresponding second chip pads, in the step of forming the base dielectric layer, the base dielectric layer covers the conductive pillars, and in the step of thinning and planarizing the base dielectric layer, the conductive pillars are shortened and exposed from the base dielectric layer to form the base conductive vias in the step of forming the base conductive vias.

3. The manufacturing method of the electronic package according to claim 1, wherein in the step of thinning and planarizing the bridge element and the base dielectric layer, a thickness of the planarized bridge element is less than a thickness of the chips.

4. The manufacturing method of the electronic package according to claim 1, wherein the base dielectric layer comprises a silicate nanocomposite material.

5. The manufacturing method of the electronic package according to claim 1, wherein the base dielectric layer comprises a composite material or an inorganic compound suitable for chemical-mechanical polishing.

6. The manufacturing method of the electronic package according to claim 1, wherein the base dielectric layer does not fill a gap between adjacent two of the bridging pads, and the base dielectric layer does not fill a gap between adjacent two of the first chip pads.

7. The manufacturing method of the electronic package according to claim 1, wherein the bridge element has a plurality of bridge conductive vias, and the chips are electrically connected to the redistribution structure via the bridge conductive vias.

8. The manufacturing method of the electronic package according to claim 1, wherein formation of the base dielectric layer comprises spray coating or spin coating.

9. The manufacturing method of the electronic package according to claim 1, further comprising:
connecting the conductive bumps to a circuit carrier; and
connecting a plurality of conductive balls to the circuit carrier.

10. An electronic package, comprising:
a sub-package, comprising:
a plurality of chips, arranged on a plane;
at least one bridge element, respectively partially overlapping with the adjacent chips, wherein a plurality of bridging pads of the bridge element are respectively directly bonded to a plurality of first chip pads of active surfaces of the adjacent chips;
a base dielectric layer, covering the chips and the bridge element, wherein the base dielectric layer fills a gap between adjacent two of the chips and exposes back surfaces of the chips, and a material of the base dielectric layer comprises a silicate composite material or a material suitable for chemical-mechanical polishing;
a plurality of base conductive vias, passing through the base dielectric layer and respectively connected to a plurality of second chip pads of the active surfaces of the chips;
a redistribution structure, disposed on the base dielectric layer and the base conductive vias; and
a plurality of conductive bumps, disposed on the redistribution structure.

11. The electronic package according to claim 10, wherein a thickness of the bridge element is less than a thickness of the chips.

12. The electronic package according to claim 10, wherein the base dielectric layer comprises a silicate nanocomposite material.

13. The electronic package according to claim 10, wherein the base dielectric layer comprises a composite material or an inorganic compound suitable for chemical-mechanical polishing.

14. The electronic package according to claim 10, wherein the base dielectric layer does not fill a gap between adjacent two of the bridging pads, and the base dielectric layer does not fill a gap between adjacent two of the first chip pads.

15. The electronic package according to claim 10, wherein a distribution density of the first chip pads is greater than a distribution density of the second chip pads.

16. The electronic package according to claim 10, wherein one of the chips is a central processing unit chip, a logic chip, a graphics processing chip, an input/output chip, a memory chip, a base band chip, a radio frequency chip, or an integrated circuit chip with a specific function.

17. The electronic package according to claim 10, wherein the bridge element has a plurality of bridge conductive vias, and the chips are electrically connected to the redistribution structure via the bridge conductive vias.

18. The electronic package according to claim 10, wherein the bridge element is an active element or a passive element.

19. The electronic package according to claim 10, further comprising:
a circuit carrier, wherein the sub-package is installed on the circuit carrier.

20. The electronic package according to claim 19, further comprising:
a plurality of conductive balls, connected to the circuit carrier.
